(19) United States
(12) Patent Application Publication
(10) Pub. No.: US 2007/0046520 A1
(43) Pub. Date: Mar. 1, 2007

(54) Electronic circuit structure using an analog-to-digital conversion concept for saving circuit pins

(75) Inventors: Spring Liu, Taipei (TW); Roger Tsai, Taipei (TW); Hao-Tai Hsieh, Taipei (TW); Sheng-Tang Chang, Taipei (TW); Wei-Kuang Chen, Taipei (TW); Yen-Chin Yang, Taipei (TW)

Correspondence Address: BACON & THOMAS, PLLC, 625 SLATERS LANE, FOURTH FLOOR, ALEXANDRIA, VA, 22314, US

(73) Assignee: INVENTEC CORPORATION, Taipei (TW)

(21) Appl. No.: 11/212,570

(22) Filed: Aug. 29, 2005

(51) Int. Cl. H03M 1/12

(52) U.S. Cl. 341/155

(57) ABSTRACT

An electronic circuit structure uses an analog-to-digital conversion concept for saving circuit pins and installs a control circuit on a main board, and the control circuit includes a processor, an analog-to-digital converter circuit, a power supply circuit and an ID generator circuit; wherein the power supply circuit is connected separately to the processor, the analog-to-digital converter circuit, and the ID generator circuit for providing a stable operating power supply; the analog-to-digital converter circuit is connected to the ID generator circuit for receiving a voltage divide power produced by the ID generator circuit and converting the voltage divide power into a digital machine ID; and the analog-to-digital converter circuit is connected to the processor for sending the machine ID. After the processor obtains the machine ID, the processor can analyze and determine the hardware configuration represented by the voltage divide power for the main board to carry out the booting operation.

### FIELD OF THE INVENTION

The present invention relates to electronic circuits, and more particularly to an electronic circuit structure that uses an analog-to-digital conversion concept for saving circuit pins.

### BACKGROUND OF THE INVENTION

At present, the design of a main board for a general traditional computer adopts a machine ID, such that after a basic input/output system (BIOS) on the main board obtains the machine ID, a hardware configuration represented by the machine ID is analyzed and determined for carrying out the traditional booting process. In the prior art design, each machine ID uses a combination of one pull up resistor and one pull down resistor. Referring to FIG. 1, the machine ID requires 8 pull up resistors 10 and 8 pull down resistors, and one end of each pull up resistor 10 is connected jointly to an operating power supply Vₛ to form a high potential level, and the other end of each pull up resistor 10 is connected separately to an end of a corresponding pull down resistor 11, and the other end of the pull down resistor 11 is jointly connected to a ground terminal V_{ground} to form a low potential level. Each pull up resistor 10 and its corresponding pull down resistor 11 are connected separately to an output terminal 12. The combined voltage potential level (which is the minimum of the high potential level) outputted by the eight output terminals 12 is outputted in a form of a machine ID comprised of a plurality of binary digits. For example, 00000001 stands for 1; 10101010 stands for 170; and 11111111 stands for 255. The voltage level of the output terminals 12 are controlled by the resistance of each corresponding pull down resistor 11.

In addition, each output terminal 12 is respectively further connected to a general purpose input output pin (GPIO Pin) on a control chip of the main board to send the machine ID to the control chip. However, the design requires eight GPIO pins for sending a machine ID (1 byte). In other words, the control chip uses up 8 pins for receiving a machine ID, not only wasting component costs, but also reducing the available space on the control circuit, which is incompliant to cost effectiveness. Therefore, finding a design of an electronic circuit capable of saving circuit pins and a way of reducing the cost of resistors, the number of GIPO pins and facilitating the identification of the configuration of a computer demands immediate attention and feasible solutions.

### SUMMARY OF THE INVENTION

In the design of a traditional computer, a machine ID is used, and each machine ID requires a pull up resistor and a pull down resistor, and each machine ID uses up a general purpose input output pin (GPIO Pin). Therefore, the inventor of the present invention based on years of experience in the related industry to develop an electronic circuit structure that uses an analog-to-digital conversion concept for saving circuit pins. The innovative design of the present invention can save the cost of resistors and the use of GPIO as well as facilitating production lines to distinguish the configuration of a computer.

Therefore, it is a primary objective of the present invention to provide an electronic circuit structure using an analog-to-digital conversion concept for saving circuit pins. The invention installs a control circuit on a main board, and the control circuit comprises a processor, an analog-to-digital converter (ADC) circuit, a power supply circuit and an ID generator circuit; wherein the power supply circuit is connected separately to the processor, the analog-to-digital converter circuit, and the ID generator circuit for providing a stable operating power supply; the analog-to-digital converter circuit is connected to the ID generator circuit for receiving a voltage divide power produced by the ID generator circuit and converting the voltage divide power into a digital machine ID; and the analog-to-digital converter circuit is connected to the processor for sending the machine ID. After the processor obtains the machine ID, the processor can analyze and determine the hardware configuration represented by the voltage divide power for the main board to carry out the booting process.

Another objective of the present invention is to use a power input terminal, a ground terminal, a voltage output terminal, a pull up resistor, and a pull down resistor module to produce the ID generator circuit; wherein an end of the pull up resistor is connected to the power input terminal for receiving the power supply from the power supply circuit through the power input terminal, and the other end of the pull up resistor is connected to an end of the pull down resistor module, and the other end of the pull down resistor module is connected to the ground terminal to serve as a zero potential level of the ID generator circuit, and the voltage output end is connected between the pull up resistor and the pull down resistor module.

A further objective of the present invention is to use a plurality of precision resistors connected in parallel with each other, and the total resistance of these precision resistors is equal to the resistance of the pull up resistor.

Another further objective of the present invention is to arrange the precision resistors in sequence on the control circuit and set a writing area adjacent to each precision resistor, so that a control circuit manufacturer can explicitly indicate the quantity of the precision resistors during the design and development of the control circuit and facilitate production, debug and maintenance personnel to check the writing area and quickly know about the machine ID produced by the ID generator circuit when checking or maintaining the control circuit.

### BRIEF DESCRIPTION OF THE DRAWINGS

FIG. 1 is a schematic view of a prior art machine ID circuit;

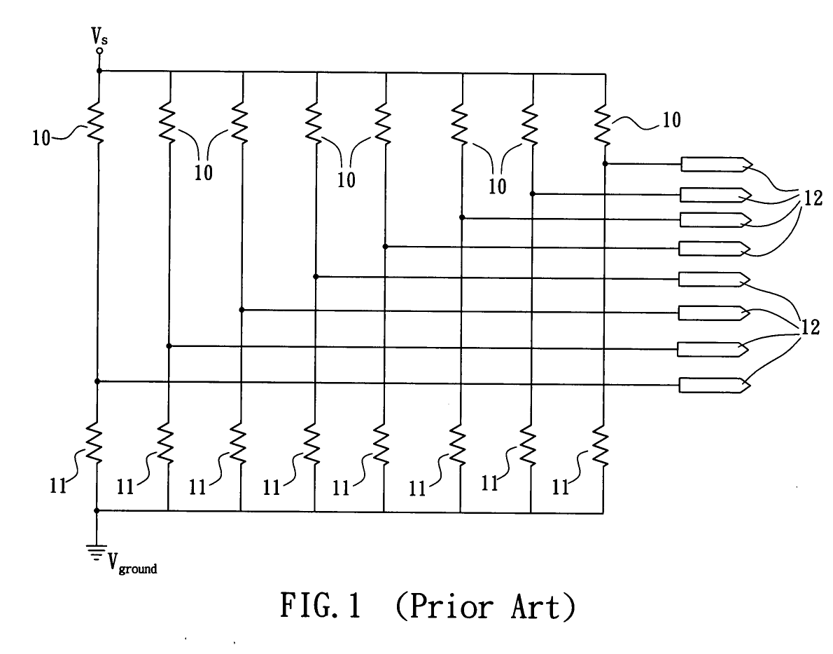

FIG. 2 is a circuit diagram of a control circuit of the invention; and

FIG. 3 is a schematic view of an ID generation circuit of the invention.

### DETAILED DESCRIPTION OF THE PREFERRED EMBODIMENTS

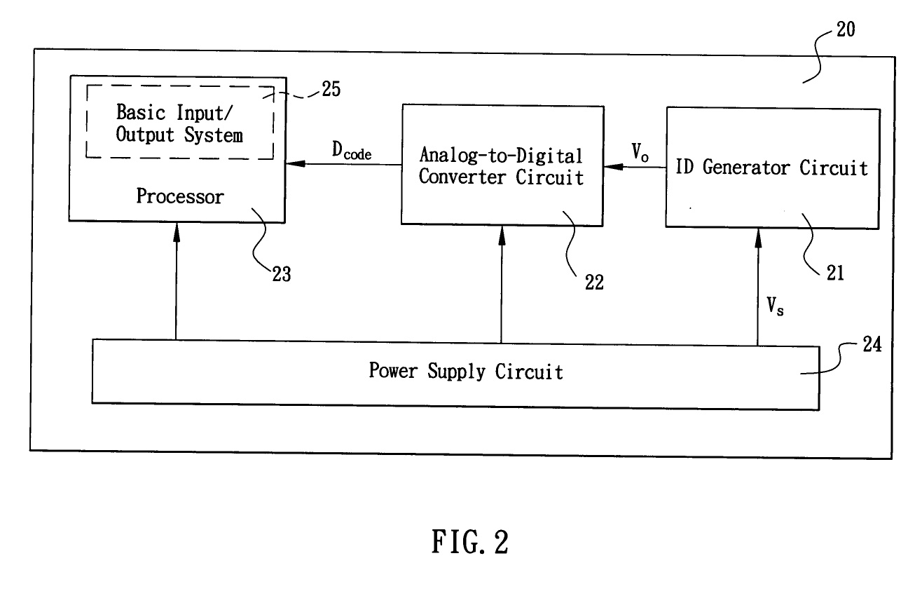

Referring to FIG. 2 for an electronic circuit structure using an analog-to-digital conversion concept for saving circuit pins, a control circuit 20 installed on a main board (not shown in the figure) comprises a processor 23, and analog-to-digital converter (ADC) circuit 22, a power supply circuit 24, and an ID generator circuit 21; wherein the power supply circuit 24 is connected separately to the processor 23, analog-to-digital converter circuit 22, and ID generator circuit 21 for providing a stable operating power supply Vₛ, and the analog-to-digital converter circuit 22 is connected to the ID generator circuit 21 for receiving a voltage divide power Vₒ produced by the ID generator circuit 21 and converting the voltage divide power Vₒ into a digital machine ID D_{code}, and the analog-to-digital converter circuit 22 is connected to the processor 23, such that the processor 23 can receive the machine ID D_{code} produced by the analog-to-digital converter circuit 22. After the processor 23 has received the machine ID D_{code}, the processor 23 analyzes and determines the hardware configuration represented by the voltage divide power Vₒ, so that the main board can carry out the booting operation. Referring to FIG. 2, the processor 23 installs a built-in basic input/output system 25 (BIOS) for storing each machine ID D_{code} and its corresponding hardware configuration. Therefore, after the processor 23 obtains the machine ID D_{code} and sends the machine ID D_{code} to the basic input/output system 25, the basic input/output system 25 will look for the hardware configuration corresponding to the machine ID D_{code}. In the meantime, the control circuit 20 manufacturer also uses a firmware update procedure to correct or add the machine ID D_{code} and its corresponding hardware configuration.

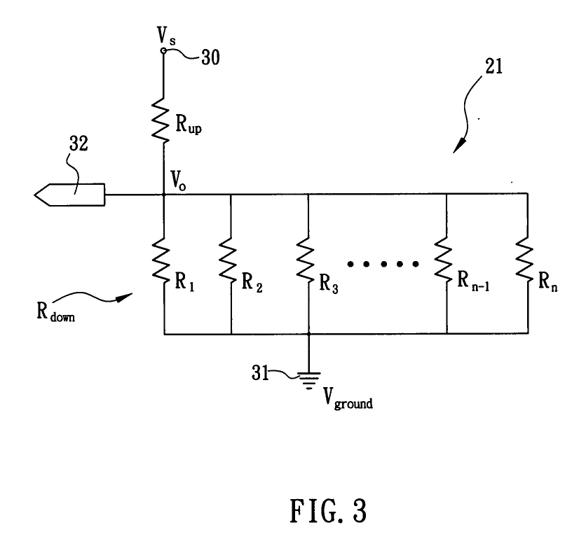

Referring to FIGS. 2 and 3, the ID generator circuit 21 comprises a power input terminal 30, a ground terminal 31, a voltage output terminal 32, a pull up resistor Rᵤₚ and a pull down resistor module R_{down}; wherein an end of the pull up resistor Rᵤₚ is connected to the power input terminal 30 for receiving an operating power supply Vₛ from the power supply circuit 24 through the power input terminal 30, and the other end of the pull up resistor Rᵤₚ is connected to an end of the pull down resistor module R_{down}, and the other end of the pull down resistor module R_{down} is connected to the ground terminal 31 to serve as a zero potential level V_{ground} of the ID generator circuit 21, and a voltage output terminal 32 is connected between the pull up resistor Rᵤₚ and the pull down resistor module R_{down}. Therefore, when the voltage divide power Vₒ is produced between the pull up resistor Rᵤₚ and the pull down resistor module R_{down}, the voltage divide power Vₒ is transmitted out of the ID generator circuit 21 through the voltage output terminal 32 for receiving the analog-to-digital converter circuit 22, where the voltage divide power Vₒ is equal to (R_{down}/(Rᵤₚ+R_{down}))×(Vₛ−V_{ground}).

In the present invention, the pull down resistor module R_{down} is a precision variable resistor (not shown in the figure) or the pull down resistor module R_{down} comprises a plurality of precision resistors R₁, R₂, R₃, . . . Rₙ₋₁, Rₙ connected in parallel with each other as shown in FIG. 3, wherein the total resistance of the precision resistors R₁, R₂, R₃, . . . Rₙ₋₁, Rₙ is designed to be equal to the resistance of the pull up resistor Rᵤₚ. The total resistance of the pull down resistor module R_{down} is represented by the formula (1/R_{down})=(1/R₁)+(1/R₂)+(1/R₃)+ . . . +(1/Rₙ₋₁)+(1/Rₙ).

In view of the description above, the operating power supply Vₛ according to a preferred embodiment of the present invention adopts a stable voltage (3 volts), and the pull up resistor Rupadopts a constant resistance (10000 ohms). The pull down resistor module R_{down} of the present invention adopts three precision resistors R₁, R₂, R₃ connected in parallel with each other, and the resistance of the precision resistors R₁, R₂, R₃ is equal to the pull up resistor Rᵤₚ (then the total resistance of the pull down resistor module R_{down} is equal to 3333 ohms), and the voltage divide power Vₒ is equal to (R_{down}/(Rᵤₚ+R_{down}))×(Vₛ−V_{ground}) (i.e. Vₒ=(3333/(10000+3333))×(3−0)=0.75 volt). Therefore, it is known that the voltage divide power Vₒ is equal to 0.25 times of the operating power supply Vₛ. In addition, the pull down resistor module R_{down} of this preferred embodiment only uses two precision resistors R₁, R₂ connected in parallel with each other. (The total resistance of the pull down resistor module R_{down} is 5000 ohms). Then, the voltage divide power Vₒ is equal to (R_{down}/(Rᵤₚ+R_{down}))×(Vₛ−V_{ground}) (i.e. Vₒ=(5000/(10000+5000))×(3−0)=1 volt). Therefore, it is known that the voltage divide power Vₒ is equal to 0.33 times of the operating power supply Vₛ. Further, the pull down resistor module R_{down} of this preferred embodiment uses a precision resistor R₁. (The total resistance of the pull down resistor module R_{down} is 10000 ohms), then the voltage divide power Vₒ is equal to (R_{down}/(Rᵤₚ+R_{down}))×(Vₛ−V_{ground}) (i.e. Vₒ=(10000/(10000+10000))×(3−0)=1.5 volts). Therefore, it is known that the voltage divide power Vₒ is equal to 0.5 times of the operating power supply Vₛ.

From the foregoing detailed description of the preferred embodiment, the total resistance of the pull down resistor module R_{down} (such as 0.25 ohm, 0.333 ohm, and 0.5 ohm) can produce a change of voltage divide power Vₒ with a constant proportion (such as 0.75 volt, 1 volt, and 1.5 volts). After the analog-to-digital converter circuit 22 has obtained the machine ID D_{code} converted from each voltage divide power Vₒ, the change with a constant proportion can be accomplished. For example, if the analog-to-digital converter circuit 22 sets the operating power supply Vₛ (which is 3 volts) as the 255^{th} level, the zero potential level V_{ground} (which is 0 volt) is set as the 0 level, and then the machine IDs D_{code} will be set as the 63.75^{th} level (when the voltage divide power Vₒ is 0.75 volt), the 85^{th} level (when the voltage divide power Vₒ is 1 volt) and the 127.5^{th} level (when the voltage divide power Vₒ is 1.5 volts). After the processor 23 has received the machine ID D_{code}, the basic input/output system 25 will analyze and determine the hardware configuration represented by the voltage divide power V₀ according to the machine ID D_{code}.

It is worth to point out that the precision resistors of the invention are arranged in sequence on the control circuit 20 and a writing area (not shown in the figure, but it could be a writing form, a circular form or sticker, etc) is set at a position adjacent to each precision resistor R₁, R₂, R₃, Rₙ₋₁, Rₙ, so that the control circuit 20 manufacturer can explicitly indicate the quantity of the precision resistors R₁, R₂, R₃, Rₙ₋₁, Rₙ during the design and development of the control circuit 20, so as to facilitate the production, debug, and maintenance personnel to directly view the writing area and quickly know about the machine ID D_{code} produced by the ID generator circuit 21 when examining or maintaining the control circuit. It is also worth to point out that the analog-to-digital converter circuit 22 can be built in the processor 23 to pack the analog-to-digital converter circuit 22 into the chip, and save cost and space.

1. An electronic circuit structure using an analog-to-digital conversion concept for saving circuit pins, being used in a control circuit and comprising:
a power supply circuit, for supplying a stable power;
a processor, coupled with said power supply circuit and having a basic input/output system for storing hardware configurations respectively corresponding to a plurality of machine IDs;
an ID generator circuit, coupled with said power supply circuit for producing a voltage divide power;
an analog-to-digital converter circuit, coupled to said power supply circuit, said processors and said ID generator circuit for:
receiving said voltage divide power, converting said voltage divide power into a machine ID,
sending said machine ID to said processor to analyze and determine a hardware configuration represented by said machine ID according to data stored in said basic input/output system, and
carrying out a booting operation according to said hardware configuration corresponding to said machine ID.

2. (canceled)

3. (canceled)

4. The electronic circuit structure of claim 1, wherein said ID generator circuit comprises:
a power input terminal, coupled with said power supply circuit for receiving an operating power supply;
a ground terminal, coupled to said power supply circuit for forming a zero potential level;
a voltage output terminal, coupled to said analog-to-digital converter circuit for transmitting said voltage divide power;
a pull up resistor, coupled with an end of said power input terminal for obtaining said operating power supply; and
a pull down resistor module, coupled with the other end of said pull up resistor and the other end of said pull down resistor module being coupled to said ground terminal to serve as a zero potential level of said ID generator circuit, and said voltage output terminal being coupled between said pull up resistor and said pull down resistor module, and a voltage divide power produced between said pull up resistor and said pull down resistor module being transmitted out of said ID generator circuit through said voltage output terminal.

5. (canceled)

6. The electronic circuit structure of claim 4, wherein said pull down resistor module comprises a plurality of precision resistors connected in parallel with each other.

7. The electronic circuit structure of claim 6, wherein said precision resistors have a total resistance equal to the resistance of said pull up resistor.

8. (canceled)
